(19) United States
(12) Patent Application Publication
(10) Pub. No.: US 2025/0210569 A1
(43) Pub. Date: Jun. 26, 2025

(54) SEMICONDUCTOR DEVICE AND MANUFACTURING METHOD OF SEMICONDUCTOR DEVICE

(71) Applicant: SHINKO ELECTRIC INDUSTRIES CO., LTD., Nagano-shi (JP)

(72) Inventors: Takumi Yumoto, Nagano (JP); Satoshi Fujii, Nagano (JP)

(21) Appl. No.: 18/982,708

(22) Filed: Dec. 16, 2024

(30) Foreign Application Priority Data
Dec. 20, 2023 (JP) 2023-214550

(51) Int. Cl. H01L 23/00; H01L 21/02; H01L 21/56; H01L 23/538; H01L 25/07; H05K 1/18

(52) U.S. Cl. CPC H01L 24/24; H01L 21/02112; H01L 23/5385; H01L 23/5389; H01L 24/32; H01L 24/73; H01L 24/83; H01L 21/56; H01L 25/072; H01L 2224/24225; H01L 2224/32225; H01L 2224/73267; H01L 2224/8384; H01L 2924/3656; H05K 1/181

(57) ABSTRACT

A semiconductor device includes an insulation base material, a wiring layer, a via, and a semiconductor element. The insulation base material includes an insulating layer including an adhesive agent layer formed on one surface of the insulating layer. The wiring layer is formed on the one surface of the adhesive agent layer. The via is separately formed from the wiring layer, and penetrates through the insulating layer and the adhesive agent layer, to be connected with the wiring layer. The via includes conductive sintered material. The semiconductor element is connected with another end of the via on an opposite side of one end of the via, the one end being connected with the wiring layer, on another surface of the insulating layer.

### CROSS-REFERENCE TO RELATED APPLICATION

This application is based upon and claims the benefit of priority of the prior Japanese Patent Application No. 2023-214550, filed on Dec. 20, 2023, the entire contents of which are incorporated herein by reference.

### FIELD

The embodiment discussed herein is related to a semiconductor device and a manufacturing method of a semiconductor device.

### BACKGROUND

Conventionally, there has been known a semiconductor device in which a semiconductor element is arranged, via an adhesive agent layer, on one surface of an insulating layer constituting an insulation base material, and a wiring layer is formed on the other surface of the insulating layer. In the above-mentioned semiconductor device, the wiring layer is bonded to the semiconductor element via a via that penetrates through the insulating layer and the adhesive agent layer.

A via hole is formed in an insulating layer and an adhesive agent layer, and further electroplating is performed on the other surface of the insulating layer and an inner wall surface of the via hole so as to integrally form the wiring layer and the via.
Patent Literature 1: Japanese Laid-open Patent Publication No. 2014-027272

However, in the above-mentioned semiconductor device, there presents a problem that the connection reliability of the wiring layer is not sufficient. Specifically, in a case where a wiring layer and a via are integrally formed by electroplating, metal to be the wiring layer and the via deposits along an inner wall surface of the via hole. Thus, a concave part denting in a depth direction of the via hole is formed in the wiring layer in a position corresponding to the via hole.

Such a concave part of the wiring layer reduces the fluidity of a bonding material, such as solder, that is supplied onto the wiring layer in a case where an external component is bonded to the wiring layer, thereby leading to occurrence of a void in the bonding material on the wiring layer. In a case where a void occurs in the bonding material on the wiring layer, electric connection and mechanical connection between the wiring layer and the external component become unstable. In other words, the connection reliability in the wiring layer of the semiconductor device may reduce.

### SUMMARY

According to an aspect of an embodiment, a semiconductor device includes an insulation base material that includes an insulating layer including an adhesive agent layer formed on one surface of the insulating layer; a wiring layer that is formed on one surface of the adhesive agent layer; a via that is separately formed from the wiring layer and penetrates through the insulating layer and the adhesive agent layer, to be connected with the wiring layer, the via including conductive sintered material; and a semiconductor element that is connected with another end of the via on an opposite side of one end of the via, the one end being connected with the wiring layer, on another surface of the insulating layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a semiconductor device according to an embodiment;

FIG. 2 is a flowchart illustrating a manufacturing method of the semiconductor device according to the embodiment;

FIG. 3 is a diagram illustrating a specific example of an insulation base material;

FIG. 4 is a diagram illustrating a specific example of a metal foil laminating process;

FIG. 5 is a diagram illustrating a specific example of a wiring layer forming process;

FIG. 6 is a diagram illustrating a specific example of a via hole forming process;

FIG. 7 is a diagram illustrating a specific example of a via hole filling process;

FIG. 8 is a diagram illustrating a specific example of a semiconductor element mounting process;

FIG. 9 is a diagram illustrating a configuration of a semiconductor device according to a modification of the embodiment;

FIG. 10 is a flowchart illustrating a manufacturing method of the semiconductor device according to the modification of the embodiment; and

FIG. 11 is a diagram illustrating a specific example of a wiring board temporary bonding process.

### DESCRIPTION OF EMBODIMENT

Hereinafter, an embodiment of a semiconductor device and a manufacturing method of the semiconductor device disclosed in the present application will be described in detail with reference to the drawings.

### EMBODIMENT

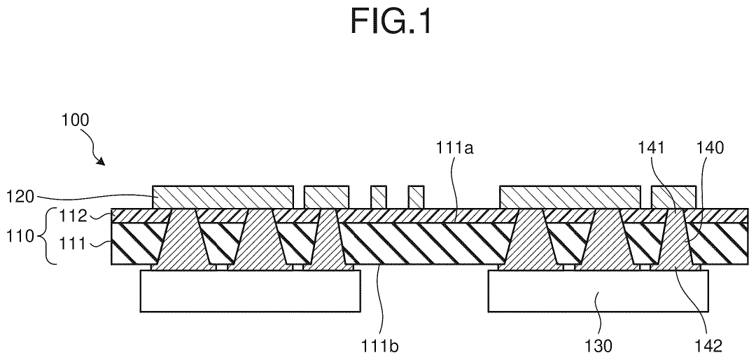

FIG. 1 is a diagram illustrating a configuration of a semiconductor device 100 according to an embodiment. In FIG. 1, a cross section of the semiconductor device 100 is schematically illustrated. The semiconductor device 100 illustrated in FIG. 1 includes an insulation base material 110, a wiring layer 120, and a semiconductor elements 130.

Note that in the following description, a surface on which the wiring layer 120 of the insulation base material 110 is formed may be referred to as an “upper surface” and a surface opposite to the surface on which the wiring layer 120 is formed may be referred to as a “lower surface”, and an up-and-down direction is prescribed therewith. However, the semiconductor device 100 may be inverted upside down when manufactured and used, for example, and further may be manufactured and used in an arbitrary posture.

The insulation base material 110 is a film-shaped member constituted of an insulating layer 111 that includes an adhesive agent layer 112 on an upper surface 111a of the insulating layer 111, so as to be a base material of the semiconductor device 100. As material of the insulating layer 111, an insulation resin material may be employed, such as a polyimide-based resin, a polyethylene-based resin, and an epoxy-based resin. A thickness of the insulating layer 111 may be approximately 25 μm to 125 μm, for example. As material of the adhesive agent layer 112, a thermosetting resin may be employed, such as an epoxy-based resin, a polyimide-based resin, and a silicone-based resin. A thickness of the adhesive agent layer 112 may be approximately 10 μm to 50 μm, for example.

The wiring layer 120 is formed on an upper surface of the adhesive agent layer 112. The wiring layer 120 is formed of copper or copper alloy, for example. A thickness of the wiring layer 120 may be approximately 50 μm to 500 μm, for example. The wiring layer 120 is electrically connected to the semiconductor elements 130 by vias 140.

The vias 140 are embedded in the insulating layer 111 and the adhesive agent layer 112 of the insulation base material 110. Conductive sintered material such as metal paste fills via holes, each of which penetrates through the insulating layer 111 and the adhesive agent layer 112, so as to form the vias 140 that are connected to the wiring layer 120. In other words, one ends 141 of the vias 140 are connected with the wiring layer 120, and other ends 142 of the vias 140 protrude from the via holes at a lower surface 111b of the insulating layer 111. As the metal paste forming the vias 140, copper paste or silver paste may be employed, for example.

The semiconductor elements 130 are sintered to the other ends 142 of the vias 140, which protrude at the lower surface 111b of the insulating layer 111. As the semiconductor elements 130, semiconductor element with the use of, for example, silicon (Si) or silicon carbide (SiC) may be employed. The semiconductor elements 130 may be ones with the use of gallium nitride (GaN), gallium arsenide (GaAs), or the like. For example, as the semiconductor element 130; a semiconductor element (for example, silicon tip such as CPU) that serves as an active element, an Insulated Gate Bipolar Transistor (IGBT), a Metal-Oxide-Semiconductor Field-Effect Transistor (MOSFET), a diode, or the like may be employed.

In the embodiment, conductive sintered material fills via holes, each of which penetrates through the insulating layer 111 and the adhesive agent layer 112, so as to separately form the vias 140 from the wiring layer 120. In other words, the wiring layer 120 is not integrally formed with the vias 140 in a case where the vias 140 are formed in via holes of the insulating layer 111 and the adhesive agent layer 112 by conductive sintered material, and an interface to be a bonding surface between the wiring layer 120 and each of the vias 140 is present between the wiring layer 120 and the vias 140. The wiring layer 120 and each of the vias 140 are separately formed, and thus a concave part denting in a depth direction of a corresponding via hole is not formed in the wiring layer 120 so that a surface of the wiring layer 120 becomes a flat surface. Thus, the fluidity is kept in bonding material such as solder, which is supplied onto the wiring layer 120 in a case where an external component is bonded to the wiring layer 120, so that it is possible to reduce occurrence of a void in the bonding material. As a result, it is possible to improve the connection reliability of the wiring layer 120 with respect to the external component.

In the embodiment, each of the vias 140 has a tapered shape in which a diameter thereof increases as a position is closer to the semiconductor element 130. In other words, in each of the vias 140, a diameter of the other end 142 connected with the semiconductor element 130 is larger than a diameter of the one end 141 connected with the wiring layer 120. As described above, each of the vias 140 has a tapered shape, and thus a bonding area between the semiconductor element 130 and the corresponding via 140 increases, so that it is possible to improve bonding strength between the semiconductor elements 130 and the vias 140.

In the embodiment, the other ends 142 of the vias 140 protrude from the lower surface 111b of the insulating layer 111. In other words, the other ends 142 of the vias 140 include edge surfaces that are positioned outside the lower surface 111b of the insulating layer 111. Thus, the other ends 142 are stably in contact with the semiconductor elements 130, so that it is possible to improve the connection reliability between the semiconductor elements 130 and the vias 140.

In the embodiment, the other end 142 of each of the vias 140 has a diameter that is larger than that of a part penetrating through the insulating layer 111 and the adhesive agent layer 112 (namely, diameter of via hole), and further extends around the via holes. In other words, each of the other ends 142 extends around the corresponding via hole at the lower surface 111b of the insulating layer 111. Thus, the other ends 142 are more stably in contact with the semiconductor elements 130, so that it is possible to further improve the connection reliability between the semiconductor elements 130 and the vias 140. Note that the other ends 142 need not to extend around the via holes at the lower surface 111b of the insulating layer 111. In this case, the edge surfaces of the other ends 142 may be positioned on the same plane as the lower surface 111b of the insulating layer 111.

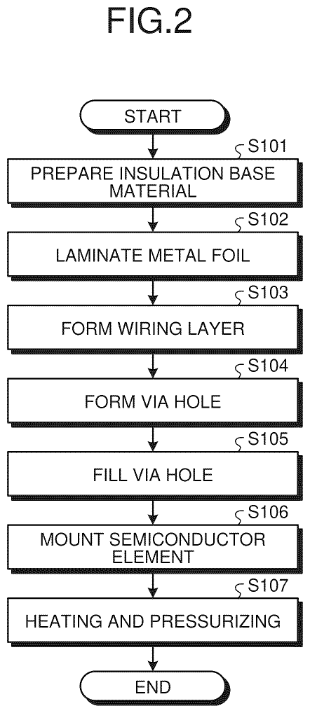

Next, a manufacturing method of the semiconductor device 100 that is configured as described above will be explained with reference to FIG. 2 while exemplifying a specific example. FIG. 2 is a flowchart illustrating a manufacturing method of the semiconductor device 100 according to the embodiment.

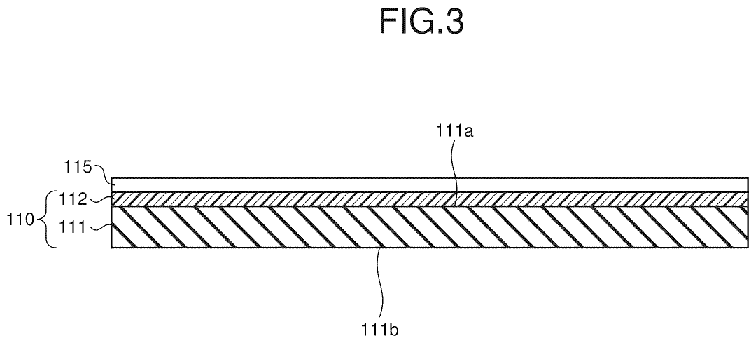

The insulation base material 110 to be a base material of the semiconductor device 100 is prepared (Step S101). Specifically, for example, as illustrated in FIG. 3, the insulation base material 110 is prepared, which is constituted of the insulating layer 111 that includes the adhesive agent layer 112 on the upper surface 111a of the insulating layer 111. FIG. 3 is a diagram illustrating a specific example of the insulation base material 110. As material of the insulating layer 111, an insulation resin material such as a polyimide-based resin, a polyethylene-based resin, and an epoxy-based resin may be employed. As material of the adhesive agent layer 112, a thermosetting resin such as an epoxy-based resin, a polyimide-based resin, and a silicone-based resin may be employed. During the step in which the insulation base material 110 is prepared, the adhesive agent layer 112 is in a semi-cured state. An upper surface (namely, surface on opposite side of insulating layer 111) of the adhesive agent layer 112 is covered by a protection film 115. As the protection film 115, a polyethylene-terephthalate film having been treated with a silicone-based mold release agent or a non-silicone-based mold release agent may be employed, for example.

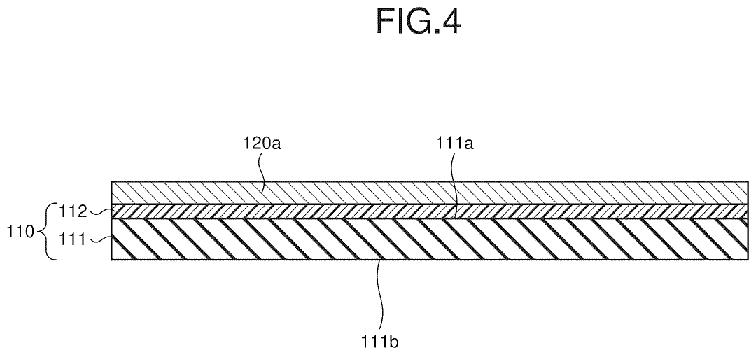

Subsequently, a metal foil to be the wiring layer 120 is laminated on an upper surface of the adhesive agent layer 112 (Step S102). Specifically, after the protection film 115 is peeled off from an upper surface of the adhesive agent layer 112, for example, as illustrated in FIG. 4, a metal foil 120a is laminated on the upper surface of the adhesive agent layer 112. FIG. 4 is a diagram illustrating a specific example of a metal foil laminating process. Similar to a thickness of the wiring layer 120, a thickness of the metal foil 120a may be approximately 50 μm to 500 μm, for example. At a step where the metal foil 120a is laminated on an upper surface of the adhesive agent layer 112, thermosetting is performed on the adhesive agent layer 112, and the metal foil 120a coheres to the adhesive agent layer 112. As material of the metal foil 120a, the metals having been exemplified as material of the wiring layer 120 may be employed. In other words, the metal foil 120a may be made of copper or copper alloy.

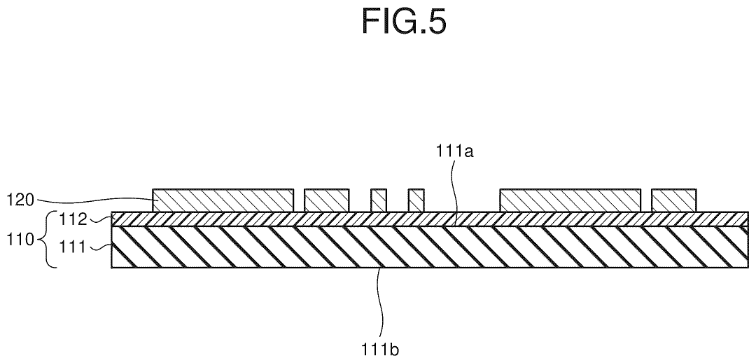

In a case where the metal foil 120a is laminated on an upper surface of the adhesive agent layer 112, the wiring layer 120 including a desired wiring pattern is formed from the metal foil 120a (Step S103). For example, the wiring layer 120 is formed from the metal foil 120a by the subtractive process. In other words, a resist layer is formed on an upper surface of the metal foil 120a, which covers a part to be left as a wiring pattern. The metal foil 120a that is exposed without being covered by a resist layer is removed by etching, for example, as illustrated in FIG. 5, and thus the wiring layer 120 is formed, which includes a desired wiring pattern. FIG. 5 is a diagram illustrating a specific example of a wiring layer forming process.

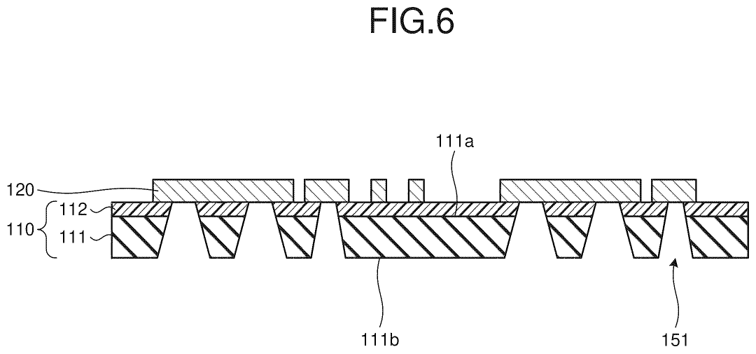

In a case where the wiring layer 120 is formed, the via holes are formed in the insulation base material 110 (Step S104). Specifically, for example, as illustrated in FIG. 6, via holes 151 are formed, each of which penetrates through the insulating layer 111 and the adhesive agent layer 112 in a thickness direction thereof so as to reach the wiring layer 120. FIG. 6 is a diagram illustrating a specific example of a via hole forming process. A lower surface of the wiring layer 120 is exposed at bottom surfaces of the via holes 151. Each of the via holes 151 has a tapered shape whose diameter decreases with a distance from the lower surface 111b of the insulating layer 111 (in other words, as position is closer to wiring layer 120). The via holes 151 may be formed by laser machining, for example.

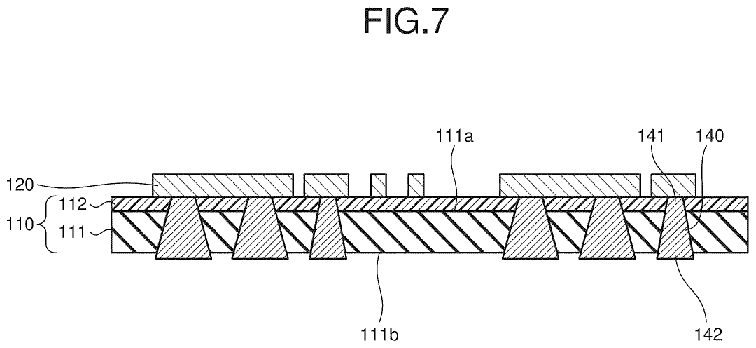

In a case where the via holes 151 are formed, conductive sintered material such as metal paste fills the via holes 151 (Step S105) so as to form the vias 140. Specifically, for example, as illustrated in FIG. 7, conductive sintered material such as copper paste or silver paste in a semi-cured state fills the via holes 151 so as to form the vias 140. In this case, the one ends 141 connected with the wiring layer 120 are formed on a side of the bottom surfaces of the via holes 151, while the other ends 142 protruding from the via holes 151 are formed on the lower surface 111b of the insulating layer 111. In other words, the sintered material in a semi-cured state leaks out from the via holes 151 at the lower surface 111b of the insulating layer 111 so as to form the other ends 142 including edge surfaces outside the lower surface 111b of the insulating layer 111. FIG. 7 is a diagram illustrating a specific example of a via hole filling process.

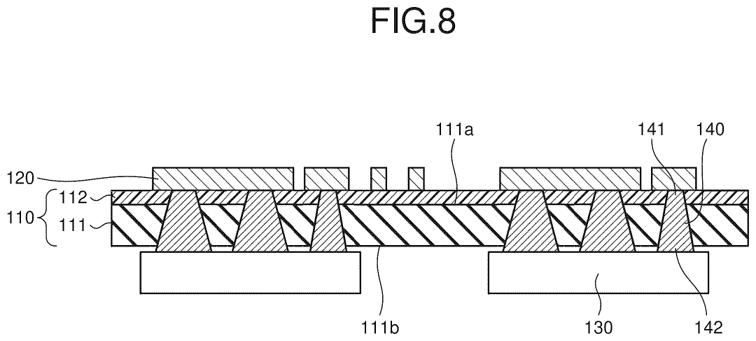

In a case where the vias 140 are formed, for example, as illustrated in FIG. 8, the semiconductor elements 130 are mounted on the side of the lower surface 111b of the insulating layer 111 (Step S106) so as to temporarily bond the semiconductor elements 130 to the other ends 142 of the vias 140. FIG. 8 is a diagram illustrating a specific example of a semiconductor element mounting process.

Electrodes of each of the semiconductor elements 130 are sintered to the other ends 142 of the vias 140 by heating and pressurizing (Step S107). In this case, on the lower surface 111b of the insulating layer 111, the other ends 142 are formed each having a diameter that is larger than that of the corresponding via hole 151. In other words, the sintered material in a semi-cured state is cured in a state where the sintered material is extending around the via holes 151 on the lower surface 111b of the insulating layer 111, so as to form the other ends 142 that are connected with the electrodes of the semiconductor elements 130 by a large contact area. Thus, it is possible to further improve the connection reliability between the semiconductor elements 130 and the vias 140. The semiconductor elements 130 are sintered to the other ends 142 of the vias 140 on the lower surface 111b of the insulating layer 111 so as to complete the semiconductor device 100.

### Modification

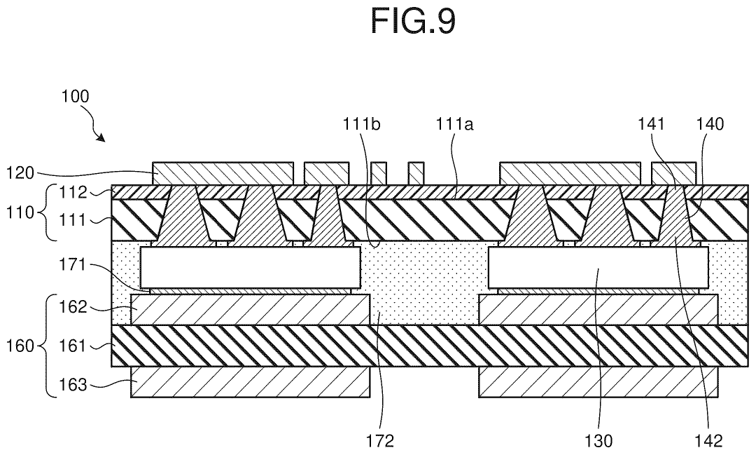

Next, modifications according to the embodiment will be explained with reference to FIG. 9 to FIG. 11. Note that in the following various modifications, the same reference symbols are respectively provided to the same parts according to the above-mentioned embodiment so as to omit duplicated explanation.

FIG. 9 is a diagram illustrating a configuration of the semiconductor device 100 according to a modification of the embodiment. The semiconductor device 100 according to the modification is different from the one according to the embodiment in including a wiring board 160.

Specifically, according to the modification, the wiring board 160 is bonded to a surface (lower surface) opposite to a surface (upper surface) bonded to the vias 140 of the semiconductor elements 130.

The wiring board 160 includes a board 161, an upper surface pad 162, and a lower surface pad 163. The board 161 is an insulating plate-shaped member, and further is a base material of the wiring board 160. The board 161 is a ceramic board that is constituted of ceramics such as an oxide-based ceramic and a non-oxide-based ceramic. As the oxide-based ceramic, for example, aluminum-oxide (Al₂O₃), zirconia (ZrO₂), or the like may be employed. As the non-oxide-based ceramic, for example, aluminum nitride (AlN), silicon nitride (Si₃N₄), or the like may be employed.

The board 161 is not limited to a monolayer insulating member, and may be a laminated board having a multilayer structure obtained by laminating an insulating layer and a wiring layer. In a case where the board 161 is a laminated board, wiring layers interposing therebetween an insulating layer are electrically connected by a via that penetrates the above-mentioned insulating layer. As material of the insulating layer, ceramics such as an oxide-based ceramic and a non-oxide-based ceramic may be employed. As material of the wiring layer, for example, cupper or copper alloy may be employed.

The upper surface pad 162 is formed on a wiring layer on an upper surface of the board 161, and further is exposed at the upper surface of the board 161 for bonding the semiconductor element 130. In a case where a lower surface of the semiconductor element 130 is bonded to an upper surface of the wiring board 160, an electrode on a lower surface of the semiconductor element 130 is bonded to the upper surface pad 162 by a sintered material 171. As material of the upper surface pad 162, similar to the wiring layer, for example, cupper or copper alloy may be employed.

The lower surface pad 163 is formed on a wiring layer on a lower surface of the board 161. As material of the lower surface pad 163, similar to the wiring layer, for example, cupper or copper alloy may be employed.

The wiring board 160 as described above is bonded to a lower surface of the semiconductor element 130, and thus the semiconductor element 130 is arranged between the wiring board 160 and the insulation base material 110. The semiconductor element 130 arranged between the wiring board 160 and the insulation base material 110 is resin-sealed by insulation resin material 172. In other words, a space between the wiring board 160 and the insulation base material 110 is filled with the insulation resin material 172 so as to cover the semiconductor elements 130. As material of the insulation resin material 172, for example, an insulation resin material such as a polyimide-based resin and an epoxy-based resin, or a resin material obtained by mixing the above-mentioned insulation resin material with filler made of silica, alumina, etc. may be employed.

As described above, in the modification, the wiring board 160 is bonded to lower surfaces of the semiconductor elements 130, so that it is possible to improve the degree of freedom in wiring layout.

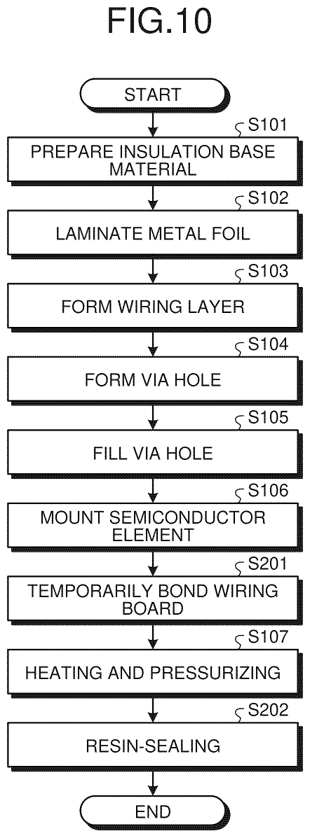

Next, a manufacturing method of the semiconductor device 100 configured as described above will be explained with reference to FIG. 10 while exemplifying a specific example. FIG. 10 is a flowchart illustrating a manufacturing method of the semiconductor device 100 according to the modification of the embodiment. In FIG. 10, parts that are the same as those illustrated in FIG. 2 are provided with the same reference symbols.

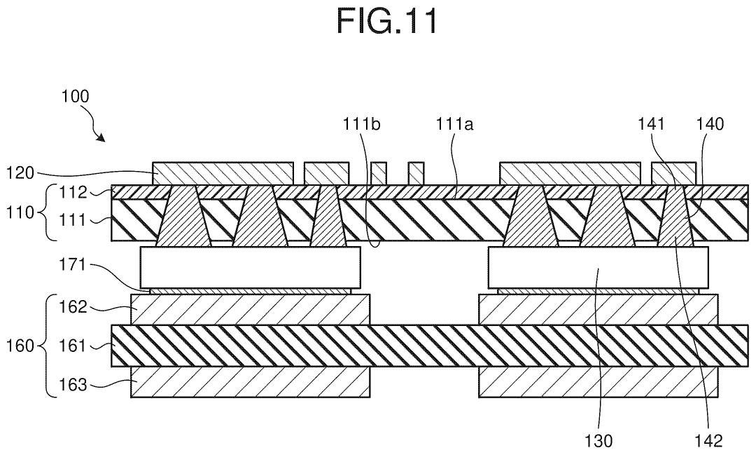

In a case where the semiconductor elements 130 and the other ends 142 of the vias 140 are temporarily bonded in processing of Step S106, lower surfaces of the semiconductor elements 130 are temporarily bonded to an upper surface of the wiring board 160 by the sintered material 171 (Step S201). Specifically, for example, as illustrated in FIG. 11, electrodes on lower surfaces of the semiconductor elements 130 are temporarily bonded to the upper surface pads 162 by the sintered material 171 in an uncured state. FIG. 11 is a diagram illustrating a specific example of a wiring board temporary bonding process.

Electrodes of the semiconductor elements 130 are sintered by heating and pressurizing with respect to the other ends 142 of the vias 140 (Step S107). Simultaneously with sintering between the other ends of the vias 140 and the electrodes of the semiconductor elements 130, electrodes on lower surfaces of the semiconductor elements 130 are sintered with respect to the upper surface pads 162 by the sintered material 171. In other words, upper surfaces of the semiconductor elements 130 are sintered with respect to the other ends 142 of the vias 140 at the lower surface 111b of the insulating layer 111, and further the wiring board 160 is bonded to lower surfaces of the semiconductor elements 130. Thus, an intermediate structure is obtained, in which the semiconductor elements 130 are interposed between the wiring board 160 and the insulation base material 110.

Next, for example, transfer molding is performed on the intermediate structure so that the semiconductor elements 130 between the wiring board 160 and the insulation base material 110 are resin-sealed by the insulation resin material 172 (Step S202). In the transfer molding, the intermediate structure is housed in a mold, and further the fluidized insulation resin material 172 is injected into the mold. Next, the insulation resin material 172 is heated up to a predetermined temperature so as to be cured. Thus, a space between the wiring board 160 and the insulation base material 110 is filled with the insulation resin material 172 and the semiconductor elements 130 are sealed so as to complete the semiconductor device 100.

As described above, a semiconductor device (as one example, semiconductor device 100) according to the embodiment includes an insulation base material (as one example, insulation base material 110), a wiring layer (as one example, wiring layer 120), a via (as one example, via 140), and a semiconductor element (as one example, semiconductor elements 130). The insulation base material includes an insulating layer (as one example, insulating layer 111) including an adhesive agent layer (as one example, adhesive agent layer 112) formed on one surface (as one example, upper surface 111a) of the insulating layer. The wiring layer is formed on the one surface (as one example, upper surface) of the adhesive agent layer. The via is separately formed from the wiring layer, and penetrates through the insulating layer and the adhesive agent layer, to be connected with the wiring layer. The via includes conductive sintered material. The semiconductor element is sintered with respect to another end (as one example, another end 142) of the via on an opposite side of one end (as one example, one end 141) of the via, the one end being connected with the wiring layer on another surface (as one example, lower surface 111b) of the insulating layer. Thus, it is possible to improve the connection reliability of the wiring layer.

According to an aspect of a semiconductor device disclosed herein, it is possible to improve the connection reliability of a wiring layer.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
an insulation base material that includes an insulating layer including an adhesive agent layer formed on one surface of the insulating layer;
a wiring layer that is formed on one surface of the adhesive agent layer;
a via that is separately formed from the wiring layer and penetrates through the insulating layer and the adhesive agent layer, to be connected with the wiring layer, the via including conductive sintered material; and
a semiconductor element that is connected with another end of the via on an opposite side of one end of the via, the one end being connected with the wiring layer, on another surface of the insulating layer.

2. The semiconductor device according to claim 1, wherein
the via has a tapered shape whose diameter of the other end is larger than a diameter of the one end.

3. The semiconductor device according to claim 1, wherein
the other end of the via protrudes from the other surface of the insulating layer.

4. The semiconductor device according to claim 3, wherein
the other end of the via has a diameter that is larger than that of a part of the via, the part penetrating through the insulating layer and the adhesive agent layer.

5. The semiconductor device according to claim 1, further comprising:
a wiring board that is bonded to a surface on an opposite side of an surface of the semiconductor element which is connected with the via.

6. A manufacturing method of a semiconductor device, comprising:
preparing an insulation base material that includes an insulating layer including an adhesive agent layer formed on one surface of the insulating layer;
laminating a metal foil on one surface of the adhesive agent layer;
forming a wiring layer from the metal foil;
forming a via hole penetrating through the insulating layer and the adhesive agent layer to the wiring layer in the insulation base material;
filling the via hole with conductive sintered material to form a via that is connected with the wiring layer; and
sintering between an electrode of a semiconductor element and another end of the via which is on an opposite side of one end of the via, the one end being connected with the wiring layer, on another surface of the insulating layer.
